(19) United States
(12) Patent Application Publication
(10) Pub. No.: US 2025/0233414 A1
(43) Pub. Date: Jul. 17, 2025

(54) ELECTRICAL VEHICLE CHARGER POWER SYSTEM INCLUDING AUTO CHARGE CURRENT SUPPLY

(71) Applicant: LEDVANCE LLC, WILMINGTON, MA (US)

(72) Inventors: Tianzheng Jiang, Shenzhen (CN); Robert Cilic, Deering, NH (US); Ming Li, Acton, MA (US)

(21) Appl. No.: 19/025,517

(22) Filed: Jan. 16, 2025

Related U.S. Application Data
(60) Provisional application No. 63/621,709, filed on Jan. 17, 2024.

(51) Int. Cl. H02J 3/12; B60L 53/62; G01R 19/165; H02J 7/00; H02J 13/00

(52) U.S. Cl. CPC H02J 3/12; B60L 53/62; G01R 19/16571; H02J 7/00304; H02J 13/00022; B60L 2250/00; H02J 2310/14

(57) ABSTRACT

The present disclosure provides methods and structures for controlling current of an electric vehicle charger. In one embodiment, the electric vehicle charger includes a sub-G communication module in electrical communication in a micro control unit of the electrical vehicle charging device, the sub-G communication module for receiving a current reading from an ammeter connected to a main breaker panel that is providing current to at least the electrical vehicle charging device; and a microcontroller including instructions for reducing the current draw of the electrical charger when the current reading from the ammeter reaches a threshold value for avoiding throwing the main disconnect breaker of the main breaker.

### TECHNICAL FIELD

The present disclosure generally relates to electrical vehicle chargers. More particularly, the present disclosure is directed to methods, systems and computer program products that can adjust current to an electrical vehicle charger.

### BACKGROUND

Internal Combustion Engine (ICE) vehicles will be replaced by Electric Vehicles (EVs) over the coming years. The purchase and use of EVs is poised to rapidly expand in the United States in the near term. It is estimated that as much as 80% of the electrical charging for these vehicles will be accomplished at the owner's residence. The typical charging requirement for EVs, where more than 1-2 hours is available for the process, will be done with a “Level II” charger. A Level II charger provides 220 Volts of charging capability, usually at 30-40 Amps. This is a significant load on the typical U.S. electric energy supply. Almost all U.S. homes have a master panel that provides 200 Amps or less of electric capacity. Many are 125 Amps or 100 Amps, which makes charging an EV a considerable percentage of the available home electric power. The cost of upgrading or replacing the master service panel in the home can be quite expensive, and in some cases, not possible. This choke point and the expense involved in upgrading the home electric service may suppress the ability for a large part of the U.S. population to move to EVs. This problem is exacerbated when the possibility of two or more EVs per home is taken into account.

Level II charging infrastructure requires expensive circuitry and wiring that is dedicated to one EV at a time. It is also the case that EVs will often occupy a parking bay, at home or in a public parking space, for hours after their EV battery packs are fully charged.

### SUMMARY

The present disclosure provides methods and structures for controlling current of an electric vehicle charger.

In one embodiment, an electrical vehicle charging device is provided that includes a sub-G communication module for receiving current reading from an ammeter connected to a main breaker panel that is separate from the electric vehicle charging device. The main breaker panel provides current to at least the electrical vehicle charging device. The electrical vehicle charging device also includes a microcontroller including instructions for reducing the current draw of the electrical charger when the current reading from the ammeter that is received by the sub-G communication module reaches a threshold value for avoiding throwing the main disconnect breaker of the main breaker panel.

In one embodiment, a method of electrical vehicle charging device is provided that can include receiving current measurements at the electric vehicle charging device with a sub-G communication module from an ammeter that is connected to a main breaker panel that is separate from the electric vehicle charging device. The main breaker panel provides current to at least the electrical vehicle charging device. The method further includes reducing the current draw of the electrical charger when the current measurements from the ammeter reaches a threshold value to avoiding throwing a main disconnect breaker of the main breaker panel.

In yet another embodiment, a computer program product is provided for electrical vehicle charging comprising a computer readable storage medium having computer readable program code embodied therewith, the program instructions executable by a processor to cause the processor to: receive, using the processor, current measurements at the electric vehicle charging device with a sub-G communication module from an ammeter that is connected to a main breaker panel that is separate from the electric vehicle charging device. The main breaker panel provides current to at least the electrical vehicle charging device. The method provided by the computer program product further includes reducing, using the processor, the current draw of the electrical charger when the current measurements from the ammeter reaches a threshold value to avoiding throwing a main disconnect breaker of the main breaker panel.

These and other features and advantages will become apparent from the following detailed description of illustrative embodiments thereof, which is to be read in connection with the accompanying drawings.

### BRIEF DESCRIPTION OF THE DRAWINGS

The following description will provide details of embodiments with reference to the following figures wherein:

FIG. 1 is an illustration of an electrical vehicle (EV) charging environment including an electrical vehicle charger that can adjust its current draw in response to the total current draw from the electrical box of a domicile, in accordance with one embodiment of the present disclosure.

FIG. 2 is an illustration of an electric vehicle (EV) charger that can adjust its current draw in response to receiving a sub-G signal transmitting data on the total current draw of a main breaker panel, in accordance with one embodiment of the present disclosure.

FIG. 3 is an illustration of one embodiment of a current measuring device installed at a power panel to facilitate electric vehicle charging with the electrical vehicle charger depicted in FIGS. 1 and 2.

FIG. 4 is a block/flow diagram that illustrates electrical vehicle charging, in accordance with one embodiment of the present disclosure.

### DETAILED DESCRIPTION

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

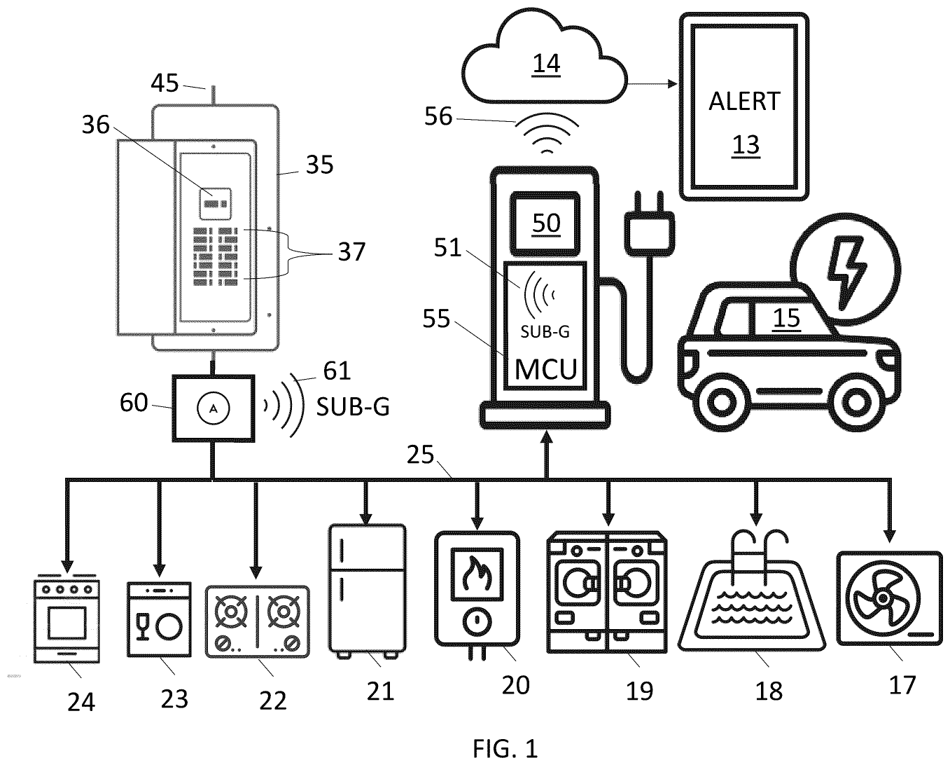

FIG. 1 is an illustration of one embodiment of an electrical vehicle charging environment. Most electric vehicle (EV) users in install their EV charging equipment 50 on the ground floor of their domicile. For example, the EV charger 50 is installed on a wall inside or outside the premises. In some examples, the EV charger 50 is supplied AC power (240 Vac) through branch supply wires 25 fed from a branch breaker from the house hold main breaker panel 35. The main breaker panel 35 includes a main disconnect breaker 36 and multiple branch circuit breakers 37 to feed other household electric loads. The main breaker panel 35 is fed by the local power utility through a metered service entrance cable 45. Typical residential service entrance supply ratings are 240 Vac with typical total current supply ampacities of 60, 100, 125, 150, 200 Amperes (Amps). The sum of the current draws (amps) of all the branch circuits 25 in the domicile cannot exceed 80% of the aforementioned total supply ampacities. The 80% rating is derived from National Electric Code requirements of not loading any circuit beyond 80% of its current rating.

In the modem domicile, electrical loads (current draws) vary throughout the day. A domicile may contain many high current drawing loads (so called “heavy” loads) such as (but not limited to) electric ovens (50 A) 24, electric ranges (50 A) 22, dishwasher (10 A) 23, central air conditioning equipment (40-60 A) 17, electric central heating equipment (80-150 A) 20, clothes dryer (40 A) 19, refrigerators 21 (3 A-15 A) and other miscellaneous current drawing loads. In yet other examples, pumps for hot tubs and pools (generally 15 A) 18 may also contribute to the electrical load.

Recently, the modern electric vehicle 15 continues to grow in popularity and requires frequent “charging” to replenish the propulsion batteries in the vehicle 15, The US department of energy (DOE) estimates that over 80% of all EV charging occurs at home. Typical residential Level 2 AC “Charger” equipment will require supply currents typically between 32 Amps to 80 Amps depending on the particular equipment used.

The proliferation of residential charging equipment, e.g., electrical vehicle charger 15, operating at the same time as other heavy loads can easily exceed the current supply capacity of the incoming electrical service 45 to the domicile. It is quite possible to have the vehicle charging 15, 50, clothes drying 19, dinner cooking 22, 24 and central air conditioning 17 all taking place simultaneously. Although the main incoming service breaker 36 will “trip” or disconnect under these abnormal load conditions, it will result in power disruption and aggravation for the homeowner along with sub-optimal charging of the homeowner's electrical vehicle 15.

The homeowner have thus two options: A) increase the size (Amp Capacity) of the incoming electrical service 45—this may or may not be possible depending on the home construction and/or utility capacity in the area and will nonetheless result in considerable expense and time expenditure to achieve; or B) consciously choose which appliances to use at one time to avoid tripping the main breaker and having a service disruption. Option B) may be technically feasible, but a major inconvenience for the homeowner.

The electrical vehicle (EV) charging equipment 50 of the present disclosure can vary its load or current demand in Amperes. However, prior to the methods, systems and computer program products of the present disclosure, various load management interlocks prevented multiple high current devices from operating simultaneously resulting in user inconvenience and dissatisfaction.

For example, one very common practice is to connect an energy meter in series to incoming electrical service entrance wires then the energy meter transmits the incoming current level to the EV charger using PLC (power line carrier) technology. This requires a direct connection between the EV charger 50, the main breaker panel 35 and the device, e.g., energy meter, that is controlling and measuring modulation of the electrical draw from the EV charger 50. Both the energy meter and the EV charger must integrate the PLC technology. In this example, when the EV charger receives the household total current value; it compares it to a preset maximum threshold setpoint and regulates the EV charging current to a value below the incoming service tripping threshold. PLC technology is expensive to implement and subject to poor reliability due to electrical noise from other electrical loads interfering with the PLC signal.

Another example, uses 2G, 3G, 4G and 5G communication technology to communicate between the energy meter and the EV charger via cloud storage technology. The operation is similar to the first solution with the charger regulating its current draw so as to limit the total service current draw. It is expensive to implement this type of communication technology which requires cellular communication modules in both the energy meter and the EV charger, and it is subject to network and internet availability for operation.

Another example uses a 2.4G wireless module such as “WiFi” or BlueTooth module in both the energy meter and the EV charger but this solution suffers from known typical 2.4G reliability issues especially if the distance between the service entrance or sub Feed Panel is greater than 10 m or has multiple solid surfaces (obstructions) from the EV charger. It is further confounded in high noise WiFi environments as typically encountered in residential neighborhoods with multiple WiFi and BlueTooth emitters.

A yet further solution is to install a dedicated hardwired LAN or ethernet type cable between the energy meter at the service entrance panel and the EV charger. The expense of such a solution is obvious and the feasibility is dictated by physical constraints such as finished living spaces and distance.

FIGS. 1-4 illustrates methods, systems and computer program products that can provide an electrical vehicle (EV) charger power system that can automatically adjust the charge current to avoid exceeding the current supply capacity of incoming electrical service from the domicile.

In some embodiments, the electrical vehicle power system that automatically adjusts charging capacity to account for potential increases in draw that exceed the capacity of the home electrical service, e.g., can trip the main breaker 36, includes at least one non-contact CTs (Current Transformers), e.g., two non-contact current transformers (CTs), as a clip-on ammeter located 60 in the service entrance panel 35 to detect the incoming total current to the domicile. The clip-on ammeter 60 including the two non-contact current transformers (CTs) are illustrated by reference number 60 in FIGS. 1-3. The Current Transformer (CT) is a type of “instrument transformer” that is designed to produce an alternating current in its secondary winding which is proportional to the current being measured in its primary. Current transformers reduce high voltage currents to a much lower value and provide a convenient way of safely monitoring the actual electrical current flowing in an AC transmission line using a standard ammeter.

Still referring to FIGS. 1-3, a sub-G communication module 51, 61 in both the clip-on ammeter 60 and the EV charger 50 to provide that the total current value measured from the clip on ammeter 60 would be transmitted in real time to the EV charger 50, continuously. These communication modules 51, 61 may be transmitters, receivers and/or transceivers.

As used herein, the term “sub-G” denotes frequencies defined as being very high frequency (VHF) and lower, as defined by the Institute for Electrical and Electronic Engineers (IEEE). The Institute for Electrical and Electronic Engineers (IEEE) has defined as standard IEEE Standard 521-1984, a system of IEEE frequency bands for electromagnetic frequencies used for radio and radar. Very high frequency (VHF) ranges from approximately 0.3 to 1 GHz, as defined by the Institute for Electrical and Electronic Engineers (IEEE). Sub-G frequency bands occupy the range of 27 Mhz-960 Mhz.

In accordance with some embodiments of the present disclosure, the frequency used for the sub-G communication modules 61 that is integrated into the clip-on ammeter 60, and the frequency used for the sub-G communication modules 51 that is integrated into the EV charger 50; can be short-range wireless communication signals having a frequency of 315 Mhz, 433 Mhz, 700 Mhz, 868 Mhz and 915 Mhz. It is noted that these examples are provided for illustrative purposes only. It is noted that any range of frequencies may also be employed using endpoints selected from the above examples, e.g., a range of 315 Mhz to 915 Mhz is suitable, or a range of 315 Mhz to 700 Mhz, is suitable for describing the frequencies employed by the Sub-G communication modules 51, 61 that are employed herein.

It is noted that sub-G communications operate at significantly lower frequencies than cellular (2G-5G) and Wifi frequencies. The lower frequency and longer wavelength characteristics allow for reliable short-range communication and obstruction penetration for low noise operation and high reliability free from network or cloud dependence. This can enable communication between an electrical vehicle charger 50 that is at a remote location from the interior of the domicile and the main breaker panel 35. This is significant, because the main breaker panel 35 may be present within a basement or within the interior of a concrete walled room. The location and building materials separating the main breaker panel 35 and the electrical vehicle (EV) charger 50 is one obstacle that can be overcome by employing sub-G frequencies for communication.

Referring to FIGS. 1-3, the EV charger 50 regulates the charger's output current to maintain the total domicile current below the preset tripping value resulting in maximum available current to be devoted to vehicle charging at any given time without the sacrifice of other heavy household load use. For example, assuming the main breaker panel 35 has a capacity of 200 amps, the system for controlling the draw of the EV charger 50 to avoid tripping the main breaker 36 can adjust the current draw by the EV charger to ensure that the total amperage of electrical devices drawing current is less than 80% of the capacity of main breaker panel 35, which is 160 amps for a 200 amp capacity main breaker panel 35. The EV charger 50 of the present disclosure can vary its load or current demand in Amperes. In some embodiments, the EV charger 50 has a maximum current demand, i.e., the maximum current demand used when charging an EV vehicle 15 at its highest capacity, e.g., high speed charging, is approximately 50 amps. More specifically, in one example, the maximum current draw for the EV charger 50 is 48 amps. However, the current draw for the EV charger 50 is adjustable, and may range from a maximum of 50 amps to substantially 0 amps, e.g., 1-3 amps. For example, the current draw from the EV charger 50 can be adjusted to be equal to: 50 A, 48 A, 45 A, 40 A, 35 A, 30 A, 25 A, 20 A, 15 A, 10 A, 5 A, 3 A, 1 A and 0 A, as well as any range of current using the aforementioned examples as endpoints for a maximum and minimum for the range, as well as any value for the current draw within those ranges.

For example, when the main breaker panel 35 has a 200 amp capacity, 80% capacity means that 160 Amps of current is available. Assuming the air conditioning (AC) is running in the domicile with a draw of 60 Amps, when the homeowner starts to cook dinner by turning on a stove 24 having a draw of 50 Amps, there is still 50 Amps of capacity left for the 200 Amp capacity main breaker panel 35 reaching the 160 Amp value that is equal to 80% of the total capacity of a 200 amp capacity main breaker panel 35. This is sufficient for the 48 Amp maximum current draw for the EV charger 50. However, if another high current appliance is turned on, such as a stove top 22, that additional 50 amps is in excess of the 160 Amp limit that is 80% of the total capacity for the 200 amp capacity main breaker panel 35. In this example, to keep from exceeding the 160 Amps, the current draw for the EV charger 50 has to be reduced to substantially 0 Amps. As will be described in further detail below, concurrently with the current draw of the electric vehicle charger 50 being reduced to avoid tripping the main breaker 36, the system sends an alert 17 to a computing device 12, such as a smart phone, for the user notifying the user that the charging rate of the EV charger 50 has changed. The alert 17 can be helpful to the user, because it can provide the user with an opportunity to reduce the current load of the domicile. In accordance with the above example, turning off one of the stoves 22, 24 can reduce the current load of the domicile by 50 Amps, which would then allow for the current draw from the EV charger 50 to be restored to its maximum charging level, e.g., a current draw of 48 Amps.

This is only one example of the present disclosure. Further, it is not necessary that the adjustment to the current draw for the EV charger 50 to be cycled from the maximum and minimum current draws.

In another example, when the main breaker panel 35 has a 200 amp capacity, assuming the air conditioning (AC) is running in the domicile with a draw of 60 Amps, when the homeowner starts to cook dinner by turning on a stove 24 having a draw of 50 Amps, there is still 50 Amps of capacity left for the 200 Amp capacity main breaker panel 35 reaching the 160 Amp value that is equal to 80% of the total capacity of a 200 amp capacity main breaker panel 35. This is sufficient for the 48 Amp maximum current draw for the EV charger 50. However, while charging, if the dishwasher is turned on, an additional 15 amps is being drawn that puts the total above the 160 Amp limit that is 80% of the total capacity for the 200 amp capacity main breaker panel 35. In this example, to keep from exceeding the 160 Amps, the current draw for the EV charger 50 has to be reduced to substantially 45 Amps. In this example, the current draw from the EV charger 50 may be reduced from the maximum current draw of 48 Amps to a reduced value of 45 Amps. With the reduced current draw of 45 Amps for the EV charger 50, the total current draw that also includes the air conditioning (50 A), the stove (50 A) and the dishwasher (15 A) is equal to a total load, e.g., 160 Amps, that is 80% of the total capacity for the 200 amp capacity main breaker panel 35.

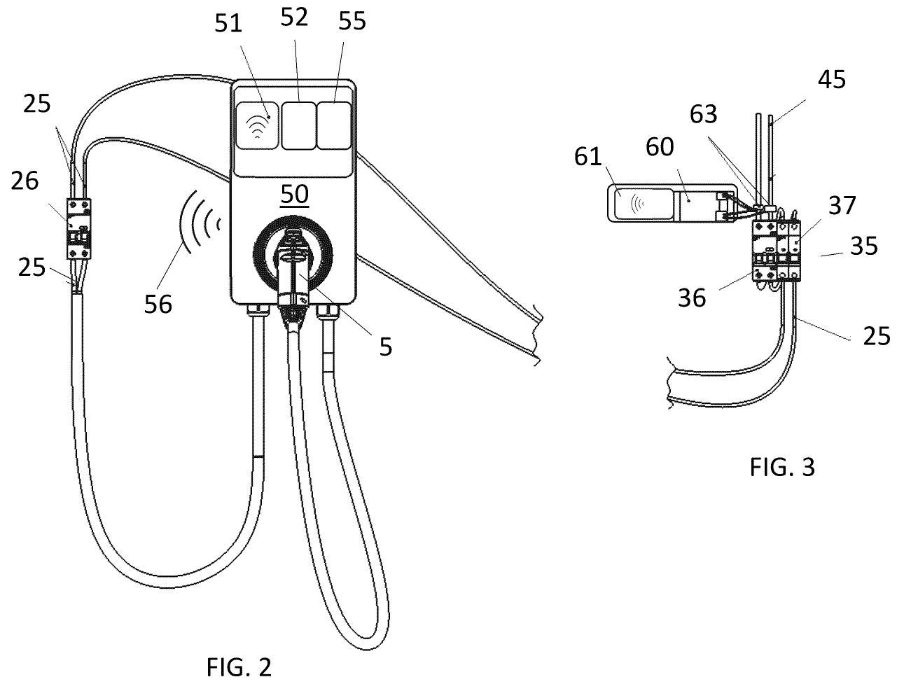

In summary, the solution offers: high reliability—significantly higher than PLC or wireless 2.4G solution; low cost solution for continuous data transmission; and no need to rewire the service entrance for an energy meter. Further details are not provided with reference to FIGS. 2-4.

FIG. 3 shows illustrates one embodiment of a clip-on ammeter 60 consisting of two CTs (Current Transformers) that clip on or surround the live main current input wires (phases) 45. As illustrated in FIG. 1, the clip-on ammeter 60 can draw power from a separate low current breaker in the same service entrance panel 35. For example, a power line is identified by 62 extending from the clip-on ammeter 60 to a lower current breaker, e.g., one of the multiple branch circuit breakers 37, in the service panel 35. It is noted that other mechanisms may be employed for powering the clip-on ammeter 60. For example, instead of wiring, e.g., via hard wiring and/or reversible plug and outlet engagements, to one of the multiple branch circuit breakers 37 in the service panel 35, the clip-on ammeter 60 may be battery powered.

In some embodiments, the engagement of the clip on ammeter 60 may be provided by an electromagnetic coil mechanism 63, e.g., provided through current transformer clamp meters. In some examples, current transformer clamp meters are equipped with rigid jaws of made of ferrite iron. The jaws are individually wrapped by coils of copper wire. Together, they form a magnetic core that can provide the electromagnetic coil mechanism 63 through which the clip on ammeter 60 can measure and monitor current draw of the electrical service being provided through the service entrance panel 35. Their basic operation is like that of a transformer. It works with one primary turn, or winding, which in nearly all cases is the conductor being measured. The coils around the jaws serve as a secondary winding of the current transformer, Current flowing through the conductor generates an alternating magnetic field that rotates around it. This field is concentrated by the clamp's iron core, inducing a flow of current in the secondary windings in the meter. The measure of the amount of magnetic field passing through the conductor (or any surface) is called magnetic flux. The signal is proportional to the ratio of the turns, A much smaller current is delivered to the meter's input due to the ratio of the number of secondary windings (those wrapped around the jaws of the clamp) vs. the number of primary windings wrapped around the core. Internally, the current flow in the conductor can be measured either as a current or can be converted to a voltage.

The principle of operation from the ammeter 60 is based on the interaction between an electric current and a magnetic field. When an electric current flows through the ammeter, it generates a magnetic field around the ammeter. The magnetic field generated by the current interacts with a permanent magnet or a coil of wire within the ammeter, causing a mechanical force that deflects a pointer on a scale. The amount of deflection is proportional to the current flowing through the ammeter, and the scale is calibrated in units of amperes (A). In analog ammeters, the mechanical force is transferred to a pointer or a needle that moves along a graduated scale to indicate the current value. Digital ammeters, on the other hand, use an electronic circuit to convert the current measurement into a numerical value that is displayed on a digital display. To ensure accurate readings, the ammeter 60 may have a very low resistance compared to the circuit being measured. This can be achieved by using a shunt resistor, which is a low-resistance resistor placed in parallel with the ammeter 60. The shunt resistor allows most of the current to flow through the circuit, while a small amount of current flows through the ammeter to provide an accurate measurement of the total current.

In the present case, the output of the ammeter 60 is transmitted to the electrical vehicle charger 50 using a sub-G communication module 51, 61 in both the clip-on ammeter 60 and the EV charger 50 to provide that the total current value measured from the clip on ammeter 60 would be transmitted in real time to the EV charger 50, continuously.

In one embodiment, the sub-G communication module 51, 61 comprises an RF transmitter and an RF receiver, both operating at a frequency of 433 MHz. The transmitter receives serial data and wirelessly transmits it through RF via its connected antenna. In some embodiments, the transmission rate can be set to 1 kbps or 10 kbps. The transmitted data is received by an RF receiver operating at the same frequency as the transmitter. This 433 MHz RF transmitter and receiver pair is cost-effective and can transmit signals up to 100 meters (although the antenna design, working environment, and supply voltage will significantly impact the effective distance).

Some further technical specifications for the 433 MHz module that can provide the elements of the sub-G communication module 51, 61 (e.g., an RF transmitter and an RF receiver, and vice versa) can include wireless (RF) simplex transmitter and receiver having an operating voltage ranging from 3V to 12V. The receiver operating current can be equal to 4 mA to 8 Ma, e.g., 5.5 mA. As noted, the operating frequency may be 433 MHz, and the transmission distance can range from 3 meters (without antenna) to 100 meters (maximum). The modulating technique can be ASK (Amplitude shift keying), and the data transmission speed can be on the order of 10 Kbps. In one example, the 433 MHz module can be provided by the ST-RX02-ASK from SUMMITEK Technology Co.

In other embodiments, the sub-G communication module 51, 61 can be provided by a HC12 transceiver module, or nRF905 transceiver module, as well as other examples specifically not denoted herein. Further, it is not required that the transmission frequency be 433 MHz. As noted above, sub-G communications can occupy 0.3 to 1 GHz. For example, the HC-12 transceiver module is a 100 mW multi-channel wireless transceiver capable of half-duplex wireless serial communication module with 100 channels in the 433.4-473.0 MHz range that is capable of transmitting up to 1 km. The NRF905 wireless transceiver module has working bands of 433/868/915 MHz. Both the HC-12 transceiver module and the NRF905 wireless transceiver module may be available from HiLetGo, Co.

Referring back to FIG. 3, Both the EV charger and ammeter have a built-in 433 Mhz sub-G module, that transmits the clip-on ammeter induced current value using the current value realized by an integrated special metering chip. The processor (MCU) in the EV Charger receives this current values from its 433 Mhz Sub-G receiver module and acts to modulate the EV charger 50 current in real time.

Referring to FIG. 2, the EV charger 50 includes an EV plug 5, a current regulator 52, a display 53, an element of the sub-g communication module 51, and an alert signal sending interface.

The EV charger 50 draws current from the electrical panel 35 through the branch supply wires 25 fed from a branch breaker 37 from the house hold main breaker panel 35. The branch supply wires 25 connecting the EV charger 50 to the electrical panel 35 may be connected and disconnected reversibly through a safety switch 26.

The EV plug 5 may have a format for the North American Charging Standard (NACS). The North American Charging Standard (NACS) is a charging connector interface standard for electric vehicles that Tesla Inc. developed and has made available for use by other charging network operators and automakers, e.g., BMW Group, Fisker, Ford, General Motors, Honda, Hyundai Motor Group, Jaguar Land Rover, Mercedes-Benz, Nissan, Polestar, Rivian, Toyota, and Volvo Cars. It is noted that this is only one example of interface standard for the EV plug 5. The EV plug may also be equivalent to combined charging system standard, e.g., CCS1 in North America and CCS2 in Europe. CCS is a direct current (DC) fast charging protocol that is Society of Automotive Engineers (SAE) certified, and is featured on vehicles produced by European and American car companies. The “combined” term in the CCS name designates its capability to incorporate the Level 2 (J1772™ standard) plug and DC fast charging connector into the same larger plug. Connector formats may further include J1772 Type 1, Type 2, GB/T, CCS type 1, CCS Type 2 and CHAdeMo.

The charger 50 also includes the sub-G communication module 51. The sub-G communication module 51 has been described above with reference to FIG. 3.

Referring back to FIG. 2, the charger further includes an electrical vehicle (EV) charge controller 52 that is in electrical communication with the sub-g communication module 51. EV Charging Controllers 52, also known as charge controllers or EVSE (Electric Vehicle Supply Equipment) controllers, are electronic devices that control the flow of electricity between the charging station and the EV's battery. The charging station constitutes a Supply Equipment Communication Controller (SECC) connected with the Power Electronics grid. The SECC and Power Electronics together comprise of the EV charge controller. The connection to the vehicle is based on Power Line Communication (PLC). However, before the PLC can be established between the vehicle and charging station, it is necessary to induce the vehicle and charging station to each other. In a following step, the charging sequence during DC charging, can begin with initialization. During initialization, the charging sequence starts by plugging in the cable from the vehicle into the charging station. This initiates a transaction into the backend.

The next stage in authentication. Once the cable has been plugged in, it is now necessary to identify how to begin charging. This can be done by using RFID authorization by the driver. The other way is through the Plug & Charge method, which is authorized centrally through certificates and ISO standards.

A parameter check is then conducted in which the vehicle exchanges charge parameters. These could include the State of Charge of the battery or power limits, perhaps required departure time. In general, information on the required energy amount.

The EV charge controller 52 can then consider charging profiles. The power manuals can generate one or several optimum charging profiles based on the charge parameters. These can then be offered to the vehicle by the communication control or the charging station.

A selected profile may be the next stage for charging. The vehicle itself can then select the charging profiles and signal it back to the charging station, which passes it to the backend. It is also possible that the vehicle generates its charging profile based on these optimum profiles. This profile can also be reported back to the charging station. The pre-requisites are that the required power should always be below the maximum power that the offered charging profile supplies.

Once all this information has been exchanged, the vehicle, charging station, and the backend have complied with the necessary. The actual power transfer can be initiated. The EV charge controller 52 controls the current during the power transfer, which translates to the draw by the EV charger 50 from the service panel 35. The EV charge controller 52 exchanges certain limits, i.e., the minimum and the maximum current values the latter can supply. Now, once the communication between these two participants is established, the power electronics continuously signals the information of its state via a protocol. For instance, measured currents, voltage, and the isolation status.

This procedure is done followed by an isolation check. The isolation check measures the isolation of DC+ and DC− to the ground. This is done to eliminate an isolation fault in the high voltage system. The isolation check also requires a validation status. It means the isolation has been checked and reported ‘ok’ back to the communication controller.

The Supply Equipment can now initiate the precharge phase. During this phase, the voltage demanded by the vehicle is put on the intermediate circuit. As soon as this has been reached, the vehicle closes its contact and establishes the connection between Power Electronics and the vehicle's battery pack.

Once the precharge phase is over, the connection has been established. The actual power transfer is executed in the charging loop. The EV charge controller 52 controls the current during the charging loop, which translates to the draw by the EV charger 50 from the service panel 35. The charging loop includes the vehicle to transmit all the target values of voltage and current in cycles to the communication controller. The communication controller passes on the required values to the power electronics and gives feedback to the vehicle's current state. This procedure continues until the battery has been fully charged or until the user or the backend stops the charging procedure.

As noted above, EV charger 50 also include a processer, e.g., micro-controller unit (MCU) 55. The MCU 55 includes data storage that can include computer readable program code embodied therewith, the program instructions executable by a processor to cause also present in the MCU 55, in which the processor to configures the EV charge controller 52 to adjust charging current from the EV charger to the EV vehicle responsive to the signal sent between the sub-G communication module 51, 61 to ensure that the current draw by the EV charger 50 does not exceed the amount of current draw that would through the main breaker 36 on the electrical panel 35, e.g., considering the total current draw by the domicile.

The processor of the MCU 55 may be embodied as any type of processor capable of performing the functions described herein. The processor may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s). The memory of the MCU 55 may be embodied as any type of volatile or non-volatile memory or data storage capable of performing the functions described herein.

The processor (MCU) 55 in the EV Charger 50 receives this current values via data signals from its element of the Sub-G receiver module 51 and acts to modulate the current draw from the EV charger 50 using EV charge controller 52 in real time, in which the current values for the EV charger 50 are selected to provide maximum charging efficiency to the electric vehicle 15 being charged while also providing the current draw for the domicile without disconnecting the electric panel 35 by throwing the main breaker panel 35. As noted above, throwing the main breaker panel 35 can occur when the current draw from the entirety of the electric charger 50 and the domicile, e.g., the elements drawing current from the branch supply wires 25 exceed the maximum allowable current draw for the electrical panel 35. As noted above, the program instructions of the elements within the MCU 55 can provide for instructions that the current draw by the EV charger 50 be modulated to ensure that the total current draw from the electrical panel 35 does not exceed 80% of the maximum current draw that the main breaker panel 35 if rated for, e.g., 200 Amps.

Referring to FIGS. 1 and 2, in some embodiments, the MCU 55 of the EV charger 50 can also provide instructions that concurrently with the current draw of the electric vehicle charger 50 being reduced to avoid tripping the main breaker 36, the system sends an alert 17 to a computing device 12, such as a smart phone, for the user notifying the user that the charging rate of the EV charger 50 has changed. The alert 17 can be helpful to the user, because it can provide the user with an opportunity to reduce the current load of the domicile. In accordance with the above example, turning off one of the stoves 22, 24 can reduce the current load of the domicile by 50 Amps, which would then allow for the current draw from the EV charger 50 to be restored to its maximum charging level, e.g., a current draw of 48 Amps.

The alert 17 can be sent by an alert wireless control module 56 in electrical communication with the MCU for the EV charger 50. The alert wireless control module 56 can send a wireless signal via a wireless communication protocol like Bluetooth, Wi-Fi and ZigBee. The alert wireless control module 56 can include an RF module to send signal, e.g., via the cloud 14, from the EV charger 50 to a user computer device, which can be provided by a phone, a tablet or even voice control device like Alexa™ and Google™ home, so that the user can make changes to the domicile current draw in person or remotely.

The wireless capabilities employed through the alert wireless control module 56 can be based upon IEEE 802.11, which is for wireless LANs (WLANs), also known as Wi-Fi. The 802.15 group of standards specifies a variety of wireless personal area networks (WPANs) for different applications. For instance, 802.15.1 is Bluetooth, 802.15.3 is a high-data-rate category for ultra-wideband (UWB) technologies, and 802.15.6 is for body area networks (BAN). The 802.15.4 category is probably the largest standard for low-data-rate WPANs. It has many subcategories. The 802.15.4 category was developed for low-data-rate monitor and control applications and extended-life low-power-consumption uses. The basic standard with the most recent updates and enhancements is 802.15.4a/b, with 802.15.4c for China, 802.15.4d for Japan, 802.15.4e for industrial applications, 802.15.4f for active (battery powered) radio-frequency identification (RFID) uses, and 802.15.4g for smart utility networks (SUNs) for monitoring the Smart Grid. All of these special versions can use the same base radio technology and protocol as defined in 802.15.4a/b.

Zigbee technologies, and similar standards based on the IEEE 802 standard for networking, can be used for sending the alert 17 using the alert wireless control module 56. ZigBee can be an enhancement to the 802.15.4 standard. These enhancements include authentication with valid nodes, encryption for security, and a data routing and forwarding capability that enables mesh networking.

Bluetooth Low Energy (BLE) (aka “Bluetooth smart”) is another standard that can be used for the alert wireless control module 56. Bluetooth low energy (BLE) is generally packaged with Bluetooth classic.

Cellular standards can also be used for the alert wireless control module 56. Any cellular standard, e.g., 2G, 3G, 4G and 5G can be used with the alert wireless control module 56. For example, the wireless standard can be 2G, such as GSM, e.g., Circuit Switched Data (CSD), GPRS, EDGE (IMT-SC) and Evolved EDGE, Digital AMPS, e.g., Cellular Digital Packet Data (CDPD), cdmaOne (IS-95), e.g., Circuit Switched Data (CSD), and combinations thereof. In another example, the wireless standard can be 3G, such as 3GUMTS, e.g., W-CDMA (air interface), TD-CDMA (air interface) and TD-SCDMA (air interface), e.g., HSPA, HSDPA, and HSPA+ etc. In another example, the wireless standard can include CDMA2000, OFDM A (air interface), EVDO, SVDO and combinations and varieties thereof. In one example, the wireless standard employed for the alert wireless control module 56 is selected to work with a 4G network, such as LTE (TD-LTE), e.g., LTE Advanced and LTE Advanced Pro; WiMax, e.g., WiMAXWiM AX-Advanced (WirelessMAN-Advanced); Ultra Mobile Broadband (never commercialized); MBWA (IEEE 802.20, Mobile Broadband Wireless Access, HC-SDMA, iBurst, has been shut down); and combinations thereof. In yet another example, the wireless standard employed for the alert wireless control module 56 is selected to work with a 5G network, such as 5G NR or 5G-Advanced.

In some embodiments, the EV charger 50 of electric vehicle supply equipment device includes a display for charging data and a mount for reversibly engaging the electric vehicle charger plug assembly. The display may be in electrical communication with the microcontroller 55.

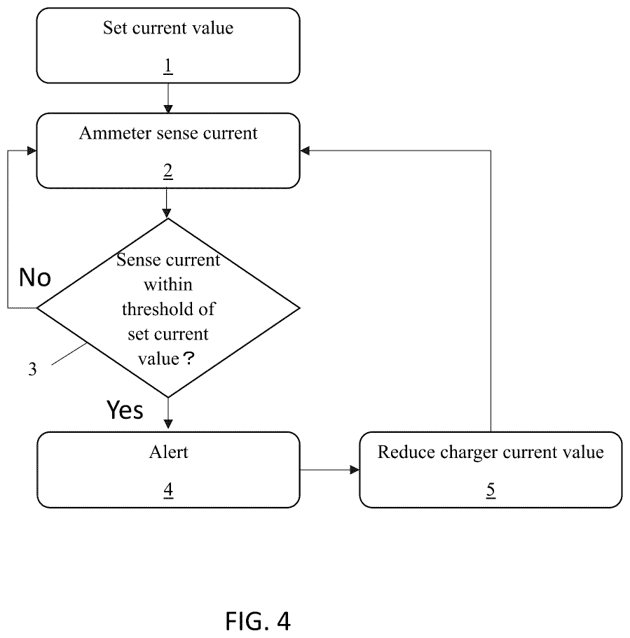

FIG. 4 illustrates one embodiment of a system workflow. The flowchart and block diagrams in the figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). These functions may be executed by the microprocessor 55. In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

This process flow may be effectuated by program instructions within the memory of the microcontroller 55 of the electrical vehicle charger 50. The microcontroller 55 receives current measurements taken for the current draw from the main panel 35 by an ammeter 60, e.g., clip on ammeter 60, proximate to the main panel 35 and in communication with the microcontroller 55 in the electric vehicle charger 50 via a sub-G communication module 51, 61, The microcontroller 55 can adjust the current draw of the electrical vehicle charger 50. For example, the microcontroller 55 can adjust current draw using the EV charge controller 52 of the EV charger 50.

In one example, a user/operator/installer can set the maximum current level. This can be the service entrance rating or sub panel maximum input current rating, as determined from the main incoming breaker. In some embodiments, a clip-on ammeter 60 transmits real time total current value to the EV charger 50. The EV charger 50 continuously compares the real time value to the set point value and takes action to reduce the EV charger 50 current demand such that total current demand for the electrical panel 35 is not exceeded.

Block 1 includes setting a current value. This is threshold current value that will trigger adjustments in current draw from the electric vehicle charger 50 to avoid throwing the main disconnect breaker 36. This represents the total current draw on the main breaker panel 35 from the domicile and the electric vehicle charger 50. This is the total current draw from the branch supply wires 25. As noted above, in some examples, this value that can be referred to as the threshold current value, may be set to be equal to 80% of the maximum current rating for the main breaker panel 35. For example, when the main breaker panel 35 has a 200 amp rating, 80% capacity means that the threshold current value will be equal to approximately 160 Amps of current.

Block 2 includes the ammeter sensing current. FIGS. 1-3 illustrate some embodiments of a clip-on ammeter 60 being connected in electrical communication with the main breaker panel 35 to measure the current draw. As noted, the clip on ammeter 60 communicates with the electrical vehicle charger over the sub-g module 51, 61 to provide real time current draw measurements from the main breaker panel 35 to the electrical vehicle charger 50. These are real time and continuous measurements.

Block 3 includes determining whether the current being measured by the ammeter 60 is within the threshold current value. If the current draw measured by the ammeter 60 does not approach the threshold current value at block 3, no adjustments are made by the current draw of the electric vehicle charger 50, and the method cycles back to block 2 for another ammeter reading in the next cycle.

If the current draw measured by the ammeter 60 does approach the threshold current value at block 3, two actions may be taken. An alert 17 may be sent to computing device 12 of the user across the alert wireless communication module 56 at block 4.

Further, when the current draw measured by the ammeter 60 does approach the threshold current value at block 3, the current draw by the electric vehicle charger 50 can be reduced to avoid potentially throwing the main disconnect breaker 36 of the main breaker panel 35. As noted above, in some embodiments, the micro-control until (MCU) 55 of the electric vehicle charger 50 can include instructions to modify current draw by the electric vehicle charger 50 when the current draw from the totality of elements drawing current from the branch supply wires 25 approaches and/or reaches the threshold current value. As noted above, current draw by the electric vehicle charger. For example, the microcontroller 55 can adjust current draw using the EV charge controller 52 of the EV charger 50.

It is noted that block 4 may be omitted.

The present invention may be a system, a method, and/or a computer program product at any possible technical detail level of integration. The computer program product may include a computer readable storage medium (or media) having computer readable program instructions thereon for causing a processor to carry out aspects of the present invention.

For example, the present disclosure provides a computer program product that includes a non-transitory computer readable storage medium having computer readable program code embodied therein for a method of providing a method for vehicle charging. The method actuated by the computer program product may include receiving current measurements at the electric vehicle charging device with a sub-G communication module from an ammeter that is connected to a main breaker panel that is separate from the electric vehicle charging device, wherein the main breaker panel is providing current to at least the electrical vehicle charging device; and reducing the current draw of the electrical charger when the current measurements from the ammeter reaches a threshold value to avoiding throwing a main disconnect breaker of the main breaker panel.

In some embodiments, the computer program product receives signal from an ammeter that comprises two non-contact current transformers reading a service entrance panel. The method that is actuated by the computer program product can further include sending an alert signal from the electrical vehicle device using an alert communications module to a computing device of a user indicating the current drawn from the main breaker panel is approaching the threshold voltage. In one embodiment, the current measurements in read in the computer program product are from electrical lines through which current is drawn from the main breaker panel that are in electrical communication with the electrical vehicle charging device as well as elements of a domicile housing the main breaker panel and drawing current from the main breaker panel. The computer program product for vehicle charging considering the drawing current from the breaker panel that results from elements of the domicile housing the main breaker panel that are said drawing current selected from the group consisting of electric ovens, electric ranges, dishwashers, central air conditioning equipment, electric central heating equipment, clothes dryers, refrigerators, pool pumps, pool heaters, hot tub pumps, hot tub heaters, and combinations thereof. In some embodiments, the computer program product employs sub-G communication module broadcast signal along a range of 315 Mhz to 915 Mhz.

In some embodiments, the computer program product employs sub-G communication module broadcast signal at 433 Mhz. In some embodiments, the threshold value used by the computer program product for avoiding throwing the main disconnect breaker is 80% of the maximum current rating for the main breaker. In some embodiments, the computer program product can control the current draw of the electrical charger using the EV charge controller, and wherein the alert communication module is provided by a wireless signal selected from the group consisting of WiFi (IEEE 802.11), Zigbee, Bluetooth, Bluetooth Low Energy (BLE), cellular standards and combinations thereof.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

Spatially relative terms, such as “forward”, “back”, “left”, “right”, “clockwise”, “counter clockwise”, “beneath,” “below,” “lower,” “above,” “upper,” and the like, can be used herein for ease of description to describe one element's or feature's relationship to another element(s) or feature(s) as illustrated in the FIGs. It will be understood that the spatially relative terms are intended to encompass different orientations of the device in use or operation in addition to the orientation depicted in the FIGs. Having described preferred embodiments of an ELECTRICAL VEHICLE CHARGER POWER SYSTEM INCLUDING AUTO CHARGE CURRENT SUPPLY, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. An electrical vehicle charging device comprising:
a sub-G communication module for receiving current reading from an ammeter connected to a main breaker panel that is separate from the electric vehicle charging device, wherein the main breaker panel is providing current to at least the electrical vehicle charging device; and
a microcontroller including instructions for reducing the current draw of the electrical charger when the current reading from the ammeter that is received by the sub-G communication module reaches a threshold value for avoiding throwing the main disconnect breaker of the main breaker panel.

2. The electrical vehicle charging device of claim 1, wherein the electrical vehicle charging device further comprises an alert communication module that sends an alert signal to a computing device of a user indicating the current drawn from the main breaker pane is approaching the threshold voltage.

3. The electrical vehicle charging device of claim 1, wherein the electrical lines from which current is drawn from the main breaker panel include branch supply wires that are in electrical communication with the electrical vehicle charging device and elements of a domicile housing the main breaker panel that are also drawing current.

4. The electrical vehicle charging device of claim 3, wherein the elements of the domicile housing the main breaker panel that are said drawing current are selected from the group consisting of electric ovens, electric ranges, dishwashers, central air conditioning equipment, electric central heating equipment, clothes dryers, refrigerators, pool pumps, pool heaters, hot tub pumps, hot tub heaters, and combinations thereof.

5. The electrical vehicle charging device of claim 1, wherein the sub-G communication module broadcast signal along a range of 315 Mhz to 915 Mhz.

6. The electrical vehicle charging device of claim 1, wherein the sub-G communication module broadcast signal at 433 Mhz.

7. The electrical vehicle charging device of claim 1, wherein the threshold value for avoiding throwing the main disconnect breaker is 80% of the maximum current rating for the main breaker.

8. The electrical vehicle charging device of claim 1, wherein said reducing the current draw of the electrical charger is controlled using the EV charge controller.

9. The electrical vehicle charging device of claim 2, wherein the alert communication module is provided by a wireless signal selected from the group consisting of WiFi (IEEE 802.11), Zigbee, Bluetooth, Bluetooth Low Energy (BLE), cellular standards and combinations thereof.

10. The electrical vehicle charging device of claim 1, wherein the ammeter comprises two non-contact current transformers reading a service entrance panel.

11. A method of electrical vehicle charging device comprising:
receiving current measurements at the electric vehicle charging device with a sub-G communication module from an ammeter that is connected to a main breaker panel that is separate from the electric vehicle charging device, wherein the main breaker panel is providing current to at least the electrical vehicle charging device; and
reducing the current draw of the electrical charger when the current measurements from the ammeter reaches a threshold value to avoiding throwing a main disconnect breaker of the main breaker panel.

12. The method of claim 11, wherein the ammeter comprises two non-contact current transformers reading a service entrance panel.

13. The method claim 11 further comprising sending an alert signal from the electrical vehicle device using an alert communications module to a computing device of a user indicating the current drawn from the main breaker panel is approaching the threshold voltage.

14. The method of claim 11, wherein the current measurements are from electrical lines through which current is drawn from the main breaker panel that are in electrical communication with the electrical vehicle charging device as well as elements of a domicile housing the main breaker panel and drawing current from the main breaker panel.

15. The method device of claim 14, wherein the elements of the domicile housing the main breaker panel that are said drawing current are selected from the group consisting of electric ovens, electric ranges, dishwashers, central air conditioning equipment, electric central heating equipment, clothes dryers, refrigerators, pool pumps, pool heaters, hot tub pumps, hot tub heaters, and combinations thereof.

16. The method of claim 15, wherein the sub-G communication module broadcast signal along a range of 315 Mhz to 915 Mhz.

17. The method of claim 11, wherein the sub-G communication module broadcast signal at 433 Mhz.

18. The method of claim 11, wherein the threshold value for avoiding throwing the main disconnect breaker is 80% of the maximum current rating for the main breaker.

19. The method of claim 11, wherein said reducing the current draw of the electrical charger is controlled using the EV charge controller, and wherein the alert communication module is provided by a wireless signal selected from the group consisting of WiFi (IEEE 802.11), Zigbee, Bluetooth, Bluetooth Low Energy (BLE), cellular standards and combinations thereof.

20. A computer program product is provided for electrical vehicle charging comprising a computer readable storage medium having computer readable program code embodied therewith, the program instructions executable by a processor to cause the processor to:
receive, using the processor, current measurements at the electric vehicle charging device with a sub-G communication module from an ammeter that is connected to a main breaker panel that is separate from the electric vehicle charging device, wherein the main breaker panel provides current to at least the electrical vehicle charging device; and
reducing, using the processor, the current draw of the electrical charger when the current measurements from the ammeter reaches a threshold value to avoiding throwing a main disconnect breaker of the main breaker panel.
